(19) United States
(12) Patent Application Publication
(10) Pub. No.: US 2011/0253310 A1
(43) Pub. Date: Oct. 20, 2011

(54) METHODS AND APPARATUS FOR AN INDUCTION COIL ARRANGEMENT IN A PLASMA PROCESSING SYSTEM

(76) Inventor: Neil Martin Paul Benjamin, Palo Alto, CA (US)

(21) Appl. No.: 13/090,863

(22) Filed: Apr. 20, 2011

Related U.S. Application Data
(60) Provisional application No. 61/326,186, filed on Apr. 20, 2010.

(51) Int. Cl. H05K 3/00; C23C 16/50; C23F 1/08

(52) U.S. Cl. 156/345.1; 118/723 R

(57) ABSTRACT

An antenna arrangement in a plasma processing system for providing plasma uniformity across a substrate during substrate processing is provided. The arrangement includes a plurality of circular antenna assemblies. Each circular antenna assembly of the plurality of circular antenna assemblies includes a set of non-circular coils. Each non-circular coil of the set of non-circular coils is offset at a predetermined angle in an azimuthal direction. The arrangement also includes a set of power generators for powering the plurality of circular antenna assemblies.

### PRIORITY CLAIM

The present invention claims priority under 35 U.S.C. 119(e) to a commonly owned provisionally filed patent application entitled “Methods And Apparatus For An Induction Coil Arrangement In A Plasma Processing System,” U.S. Application No. 61/326,186, Attorney Docket No. P1744P/LMRX-P142P1, filed on Apr. 20, 2010, by inventor Neil Benjamin, all of which is incorporated herein by reference.

### BACKGROUND OF THE INVENTION

Advances in plasma processing have facilitated growth in the semiconductor industry. The semiconductor industry is a highly competitive market. The ability for a manufacturing company to be able to process substrate at higher yield and lower cost may give the manufacturing company an edge over the competitor. Thus, manufacturing companies have dedicated time and resources to identify methods and/or arrangements for improving substrate processing.

In general, plasma processing systems may be constructed from a plurality of configurations. For example, a plasma processing system may be configured as an inductively-coupled plasma (ICP) processing system. A common ICP configuration, i.e., TCP™ (transformer coupled plasma), may be employed by placing a planar coil, e.g., induction coil, on top of a plasma processing chamber. Basically, the planar induction coil may be a flat antenna assembly.

As the term is employed herein, the induction coil is a device, similar in purpose to a transformer, that induces a time-varying voltage and potential difference in the plasma processing gases to create a plasma by successively turning the current on and off in the primary coil.

However, in recent years, the types of electronic devices that may be processed have become more sophisticated and may required more process control. In an example, electronic devices being processed may be smaller and may require more precise control of plasma parameters, such as plasma density and uniformity across the substrate, for better yield. Thus, the existing design of TCP™ induction coil for the plasma system may fall short of delivering a plasma processing solution with desired uniform plasma density across the substrate to process next-generation substrates.

Consider the situation wherein, for example, a substrate is being processed in the inductively-coupled plasma processing system. The substrate may be disposed above a lower electrode. The lower electrode may be grounded or may be powered with a first RF generator. RF power to lower electrode may be delivered through an RF match. In an example, RF match may be employed to maximize power delivery to the plasma system.

During plasma processing, a second RF generator may supply RF power to the inductor coil. The typical inductor coil being employed in a TCP system may be a spiral coil with an air core being disposed above a dielectric window. The power from the second RF generator to the inductor coil may generate an oscillating magnetic field around the coil, which penetrates into plasma and produces an azimuthal electric field penetrating through the dielectric window. The inductively coupled azimuthal electric field may generate electrical current that may interact with gas to ignite and sustain plasma.

In an ideal plasma processing system, the azimuthal electric field is zero on the axis and zero on the periphery, thereby peaking in an annular region at roughly half the radius. Plasma density, in the ideal plasma processing system, may be uniform in both the azimuthal and/or radial directions. However, typical plasma processing system may be far from ideal, and the inductor coil may be limited by various design constraints.

As may be appreciated from the foregoing, the planar inductor coil on top of the TCP™ chamber may be employed to induce a time-varying electric current in the plasma processing gases to ignite and/or sustain plasma. Thus, any non-uniformity in the induction coil may contribute to non-uniform plasma density across the substrate, potentially affecting yield.

The Galaxy™ coil on the Kiyo™ plasma processing system available from Lam Research Corporation of Fremont, Calif. may be a TCP™ inductor coil arrangement designed to address the aforementioned plasma density non-uniformity problems. In an example, the Galaxy™ coil design may employ two sets of double spiral coil assemblies.

The two sets of double spiral coil assemblies may comprise of an inner double spiral coil assembly and an outer double spiral coil assembly. The inner and outer coil assemblies design may be employed to address the plasma radial non-uniformity. Each set of coil assembly may be independently powered and/or controlled to minimize plasma density non-uniformity in the radial direction.

By employing the double spiral coil assemblies, the Galaxy™ coil arrangement may be dipole invariant, i.e., the dipole moments may be symmetric to a 180 degree rotation in the azimuthal direction. However, the plasma density may not be quadrupole invariant, i.e., the quadrupole moments may be asymmetric to a 90 degree rotation in the azimuthal direction. The amplitude of the quadrupole moments may be as high as about one percentage.

In general, a spiral coil may be configured with at least two ends, e.g., an inner end and an outer end. The spiral coil may require RF feed to be supplied to a terminal point at the inner end of the spiral coil and to a terminal point at the outer end of the spiral coil. To make the electrical connection, a bridge in the radial direction may be required between the terminal points. Since the terminals points of the spiral coil may not be close together, a looping magnetic field from the RF feed at the terminal points may induce additional non-uniformity in plasma.

As may be appreciated from the foregoing, plasma density non-uniformity in ICP processing system may be contributed by the inductor coil design. Although the Galaxy™ coil arrangement may attempt to address some of the plasma density non-uniformity in the azimuthal and/or radial directions, enhanced plasma density uniformity is needed to process substrates with higher population density of smaller feature electronic devices. Given the need to stay competitive in the semiconductor industry, enhancements to the design of TCP inductor coil arrangements are highly desirable.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows, in accordance with an embodiment of the invention, a simplified schematic of an isometric view from the bottom of the coil side of an arrangement of antenna assemblies.

FIG. 2 shows, in accordance with an embodiment of the invention, a simplified schematic of an isometric view from the top of the terminal side of an arrangement of antenna assemblies.

FIG. 3A shows, in accordance with an embodiment of the invention, a simplified schematic of the bottom view of the coil side of an outer set of coils.

FIG. 3B shows, in accordance with an embodiment of the invention, a simplified schematic of the top view of the terminal side of an outer set of coils.

FIG. 4A shows, in accordance with an embodiment of the invention, a simplified schematic of the bottom view of the coil side of an inner set of coils.

FIG. 4B shows, in accordance with an embodiment of the invention, a simplified schematic of the top view of the terminal side of an inner set of coils.

FIG. 5 shows, in accordance with an embodiment of the invention, a simplified schematic of a set of four non-circular coils circularly interlaced.

FIG. 6 shows, in accordance with an embodiment of the invention, a simplified schematic of the bottom view of a coil side of an arrangement of antenna assemblies.

FIG. 7 shows, in accordance with an embodiment of the invention, a simplified schematic of the top view of a terminal side of an arrangement of antenna assemblies.

FIG. 8A-C show, in accordance with embodiments of the invention, three different views of a terminal block.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In accordance with embodiments of the invention, there are provided methods and arrangements for configuring a plasma processing system with a circular antenna assembly to enhance plasma uniformity across a substrate. Embodiments of the invention include a plurality of non-circular coils being circularly interlaced by employing PCB fabrication technologies to implement the circular antenna assembly. Embodiments of the invention enable circular antenna assembly to be implemented with enhanced azimuthal symmetry, radial uniformity, capacitive coupling, multiple line feeds symmetry, and/or manufacturability.

In an embodiment, an arrangement with a plurality of circular antenna assemblies may be configured to improve radial uniformity of plasma. For example, at least two completely separate circular antenna assemblies, e.g., an inner circular antenna assembly and/or an outer circular antenna assembly, may be implemented. In an embodiment, each antenna assembly may be independently driven to optimize plasma density in the radial direction. Thus, plasma uniformity in the radial direction across a substrate may be enhanced through localized control.

In an embodiment, the circular antenna assembly may be configured with a plurality of non-circular coils being circularly interlaced. In an example, the circular antenna assembly may be configured with a set of four non-circular coils. In an embodiment, the four non-circular coils may be identical. In an embodiment, each non-circular coil may be offset from the other non-circular coil by a pre-determined angle in the azimuthal direction. In an example, the pre-determined offset angle may be 90 degrees for a set of four non-circular coils. In an embodiment, the circular antenna assembly may be quadrupole invariant resulting in enhanced azimuthal symmetry. Thus, plasma uniformity in the azimuthal direction across a substrate may be enhanced through improved inductor coils design.

In an embodiment, a circular antenna assembly may be fabricated employing PCB technologies. The PCB may be configured with at least two sides, e.g., a coil side and a terminal side. In an embodiment, each non-circular coil may be configured with a plurality of segments. In an example, the non-circular coil may be configured with at least four segments. In an embodiment, each segment may be configured with a plurality of vias at each end of each segment. For example, the non-circular coil may be implemented by configuring at least two segments on the coil side and/or at least two segments on the terminal sides. A first segment on the coil side may be coupled to a second segment on the terminal side by employing the vias. By employing multiple layers PCB, inter-layer vias, plurality of segment, a plurality of non-circular coils may be circularly interlaced to form a circular inductor coil arrangement.

By employing circular interlacing of a plurality of non-circular coils offset by a predetermined angle, the circular antenna assembly may be implemented with azimuthal symmetry. In addition, the plurality of non-circular coils circularly interlaced may be implemented as to prevent the non-circular coils from having physical contact to prevent causing a short. Furthermore, the plurality of circular coils being circularly interlaced may benefit from mutual flux coupling to achieve the behavior of higher inductance of multiple-turns coil.

In an embodiment, the surface area of the segments of the coils on the coil side of the PCB may be maximized to accentuate capacitive coupling with plasma. By increasing surface area of the segments on the coil side of the PCB to enhance capacitive coupling, circular antenna assembly may be employed to reliably ignite and/or sustain plasma in conditions unfavorable to inductive coupling, e.g., low power and/or electro-negative gases.

In an embodiment, RF feed may be implemented along any point on the non-circular coil through the terminals on the circular antenna assembly. The RF feed to the coils may be separated and externally synchronized, in an embodiment. In another embodiment, the RF feed to the coils may be operated in a balanced fashion, i.e., push pull arrangement so that the net capacitive current is zero. In an embodiment, the RF feed to the coils may be operated in an unbalanced fashion to increase control at low power by employing capacitive coupling.

The features and advantages of the present invention may be better understood with reference to the figures and discussions (with prior art mechanisms and embodiments of the invention contrasted) that follow.

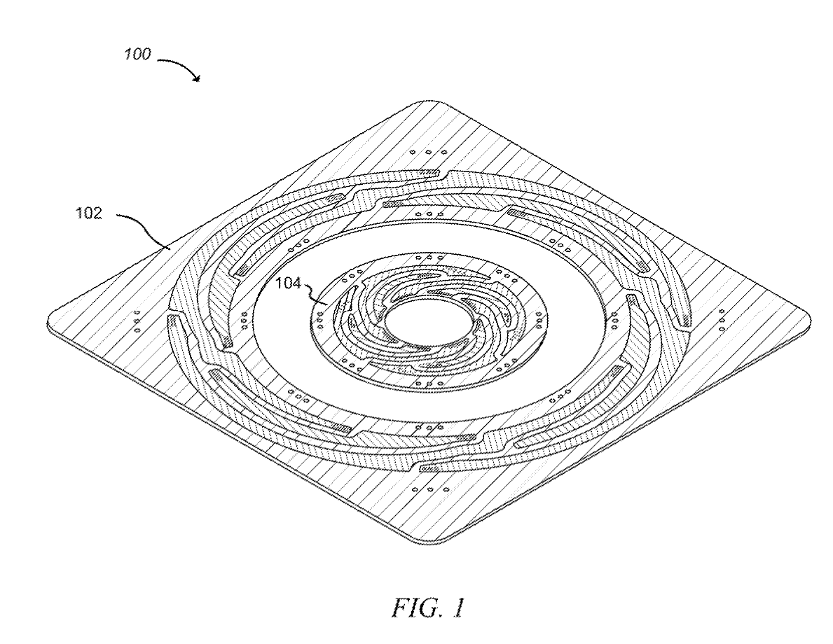

FIG. 1 shows, in accordance with an embodiment of the invention, a simplified schematic of an isometric view from the bottom of the coil side of an arrangement of antenna assemblies 100. As the term is employed herein, the coil side is the bottom side of the antenna assemblies facing the plasma.

In an embodiment, arrangement of antenna assemblies 100 may be fabricated employing a printed circuit board (PCB). The arrangement may be implemented with a plurality of antenna assemblies. In the implementation of FIG. 1, arrangement of antenna assemblies 100 may include, but not limited to, an outer antenna assembly 102, i.e., set of coils, and/or an inner antenna assembly 104, in an embodiment. In an embodiment, an inner radius of inner antenna assembly 104 may be different from an inner radius of outer antenna assembly 102. An outer radius of inner antenna assembly 104 may be different from an outer radius of outer antenna assembly 102. Outer antenna assembly/set of coils 102 and/or inner antenna assembly 104 may be independently powered and/or controlled to be optimized for plasma density uniformity in the radial direction.

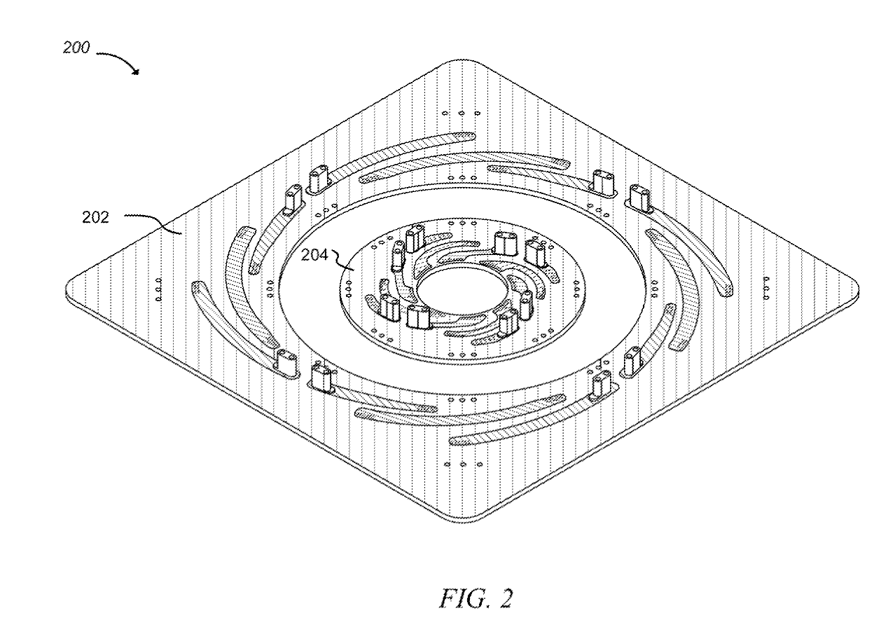

FIG. 2 shows, in accordance with an embodiment of the invention, a simplified schematic of an isometric view from the top of the terminal side of an arrangement of antenna assemblies 200. As the term is employed herein, the terminal side is the top side of the antenna assembly configured with terminals to provide energy feed to the coils. FIG. 2 is discussed in relation to FIG. 1 to facilitate understanding.

In an embodiment, arrangement of antenna assemblies 200 may be fabricated employing a printed circuit board (PCB). As shown in FIG. 2, arrangement of antenna assemblies 200 is the top view of the terminal side of arrangement of antenna assemblies 100 of FIG. 1.

Arrangement of antenna assemblies 200 may include, but not limited to, an outer antenna assembly 202 and/or an inner antenna assembly 204, in an embodiment. Outer set of coils/antenna assembly 202 of FIG. 2, showing the terminal side, is the top view of outer set of coils 102 of FIG. 1. Analogously, inner set of coils 204 of FIG. 2, showing the terminal side, is the top view of inner set of coils 104 of FIG. 1. Outer set of coils 202 and/or inner set of coils 204 may be independently powered and/or controlled to be optimized for plasma density uniformity in the radial direction, in an embodiment. Thus, radial plasma uniformity may be enhanced through localized control to improve yield.

Furthermore, these set of coils besides differing in the inner and outer radii may be implement with different numbers of effective turns, may be powered at different frequencies, may be powered to different degrees, and/or may be operated in series and/or in parallel with different splitting arrangements, in accordance with embodiments of the invention.

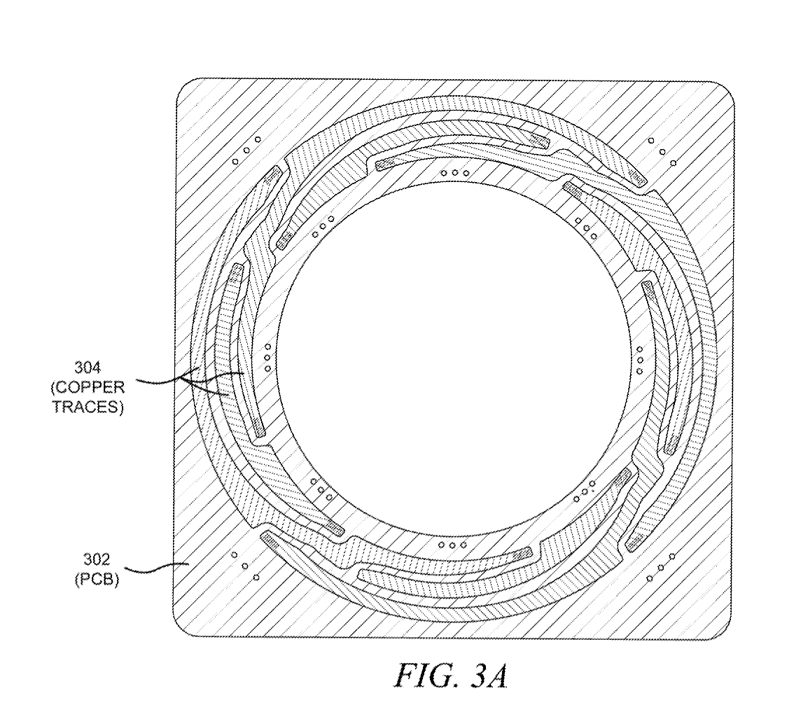

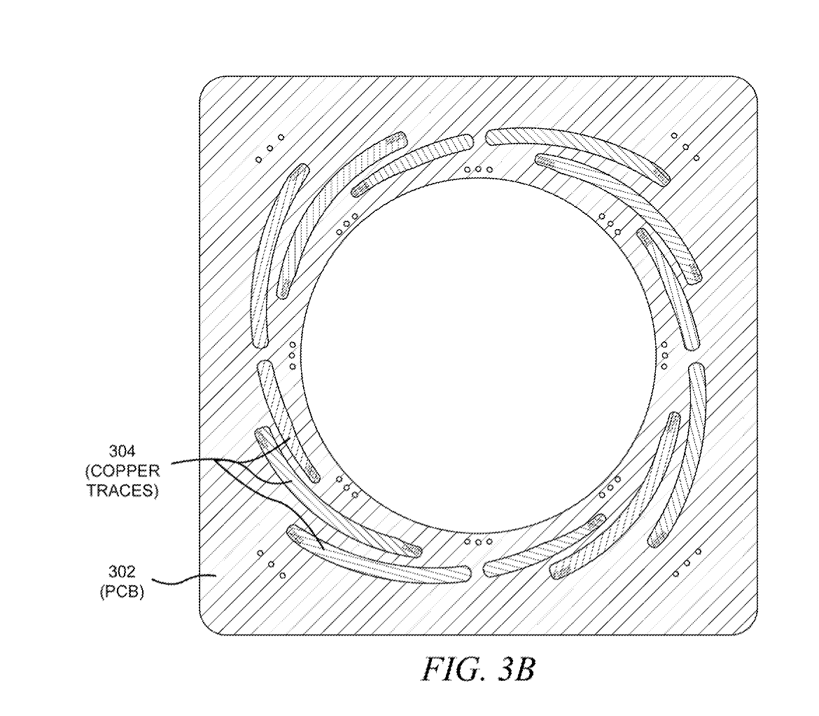

As shown in FIG. 1 and FIG. 2, the PCB may be configured with two sides, e.g., the coil side and the terminal side. The outer antenna assembly may be configured with four sets of non-circular coils circularly interlaced. The inner antenna assembly may also be configured with four sets of non-circular coils circularly interlaced. An implementation of circularly interlacing four sets of non-circular coils will be discussed in detailed in FIGS. 3A, 3B, 4A, 4A, and 5.

FIG. 3A shows, in accordance with an embodiment of the invention, a simplified schematic of the bottom view of the coil side of an outer set of coils. FIG. 3B shows, in accordance with an embodiment of the invention, a simplified schematic of the top view of the terminal side of an outer set of coils. FIG. 3B shows the traces of the segments without any of the terminals to simplify illustration.

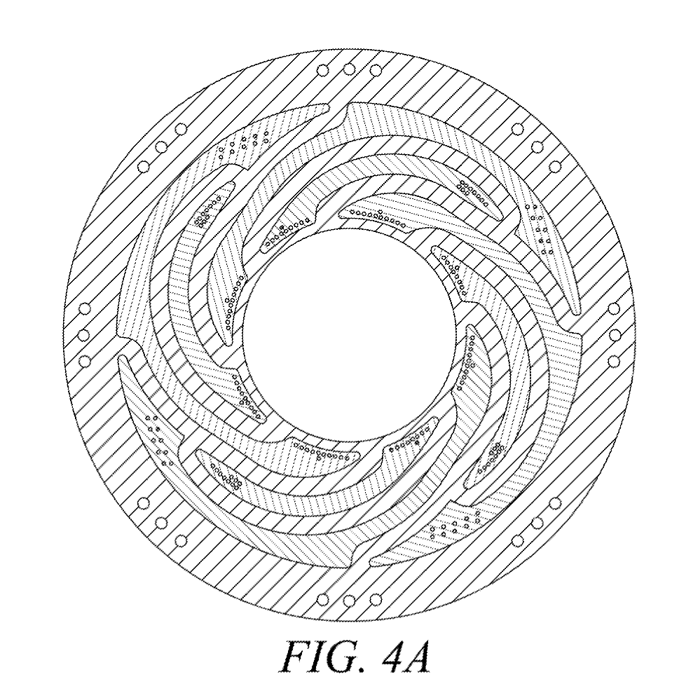

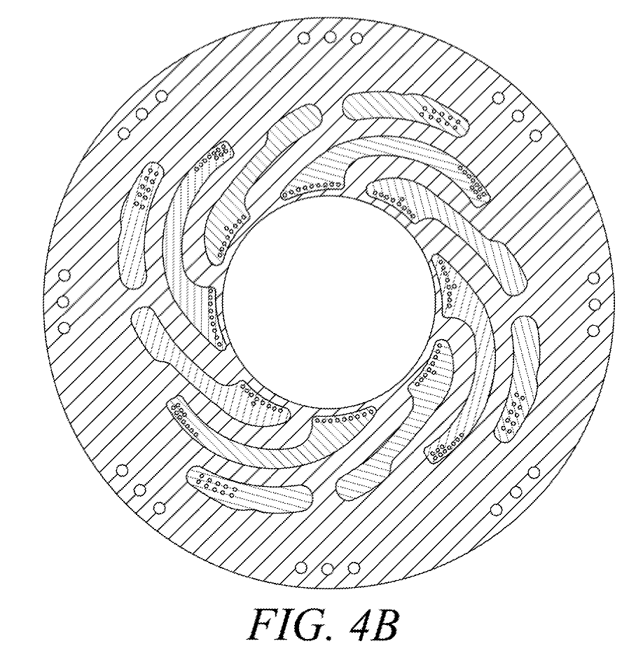

FIG. 4A shows, in accordance with an embodiment of the invention, a simplified schematic of the bottom view of the coil side of an inner set of coils. FIG. 4B shows, in accordance with an embodiment of the invention, a simplified schematic of the top view of the terminal side of an inner set of coils. FIG. 4B shows the traces of the segments without any of the terminals to simplify illustration.

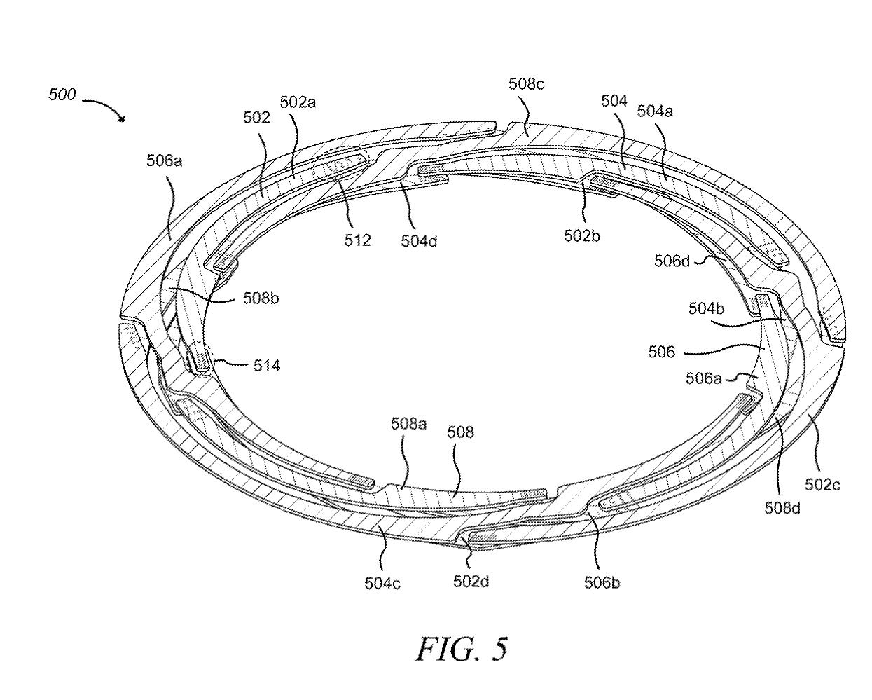

An example of circularly interlacing a set of four non-circular coils for the outer antenna assembly will be discussed below employing FIGS. 3A, 3B and 5. The circular interlacing a set of four non-circular coils for the inner antenna assembly of FIGS. 4A and 4B may be performed in a similar manner.

FIG. 5 shows, in accordance with an embodiment of the invention, a simplified schematic of a set of four non-circular coils circularly interlaced. The view of the coils is from the coil side of the antenna assembly.

As shown in FIG. 5, the set of four non-circular coils may be derived at by flipping and placing the terminal side of the outer set of coils of FIG. 3B on top of the coil side of the outer set of coils of FIG. 3A. A support material 302, e.g., PCB, may be dissolved away to leave behind copper traces 304 to form the set of four non-circular coils of FIG. 5.

In an embodiment, a non-circular coil may be configured as a plurality of segments, i.e. copper traces 304 of FIGS. 3A and 3B. Referring to FIG. 5, a first non-circular coil 502 may be implemented with at least four segments 502a, 502b, 502c, and 502d, in an embodiment. Each segment may be configured with a plurality of vias at each end of the segment, in an embodiment. In an example, segment 502a may be configured with a first set of plurality of vias 512 at a first end and/or a second set of plurality of vias 514 at a second end, in an embodiment. The vias may be employed to couple a first end of a first segment to a second end of a second segment.

As the term is employed herein, vias are holes on the PCB that may allow a first conductive trace, i.e., segment, on a first side of a PCB to be connected to a second conductive trace on a second side of a PCB. In an embodiment, the segments may be fabricated as conductive traces 304 on each sides of the PCB as shown in FIGS. 3A, 3B, 4A, and 4B.

Consider the situation wherein, for example, first non-circular coil 502 may be circularly interlaced by employing four segments disposed on two different sides/planes of the PCB, in an embodiment. Aforementioned, the PCB is not shown to simplify the illustration of circularly interlacing a set of four non-circular coils employing a set of four segments for each non-circular coil. In an example, first segment 502a and third segment 502c may be disposed on the first side, e.g., the coil side, of the PCB. Second segment 502b and fourth segment 502d may be disposed on the second side, e.g., the terminal side, of the PCB.

In an embodiment, first segment 502a disposed on the coil side of the PCB may be coupled to second segment 502b disposed on the terminal side of the PCB. Second segment 502b may be coupled to third segment 502c disposed on the coil side of the PCB. Third segment 502c may be coupled to fourth segment 502d disposed on the terminal side of the PCB.

The coupling of the four segments 502a-502d, disposed on two different planes of the PCB, may be accomplished through aligning and overlapping the plurality of vias on the ends of each segment to circularly interlace the four segments between the two planes of the PCB to form non-circular coil 502, in an embodiment. For example, the coupling in the z-direction may be implemented by aligning and overlapping the plurality of vias on a second end of first segment 502a with the plurality of vias on a first end of second segment 502b. By employing the vias to couple the segments in the z-direction between the two planes of the PCB, the segments disposed and arranged on two different planes of the PCB may be coupled in the z-direction and interlaced between the two planes to form the non-circular coil.

In the implementation of FIG. 5, a second non-circular coil 504 configured with four segments 504a, 504b, 504c, and 504d may be similarly circularly interlaced, in an embodiment. Second non-circular coil 504 may be offset at a 90 degree angle in the azimuthal direction from first non-circular coil 502, in an embodiment. A third non-circular coil 506 also configured with four segments 506a, 506b, 506c, and 506d may also be circularly interlaced, in an embodiment. Third non-circular coil 506 may be offset at a 90 degree angle in the azimuthal direction from second non-circular coil 504, in an embodiment. In another embodiment, a fourth non-circular coil 508 configured with four segments 508a, 508b, 508c, and 508d may also be circularly interlaced. Fourth non-circular coil 508 may be offset at a 90 degree angle in the azimuthal direction from first non-circular coil 506, in an embodiment. Thus, the set of four non-circular coils 502, 504, 506, and 508 may be circularly interlaced to form a circular antenna assembly 500, in an embodiment.

The circular antenna assembly may be implemented by circularly interlacing a plurality of non-circular coils between the two planes of the PCB, in an embodiment. In the implementation of FIG. 5, circular antenna assembly 500 may be configured with a set of four identical non-circular coils circularly interlaced. Each non-circular coil may be arranged eccentrically to offset 90 degrees from the next non-circular coil in the azimuthal direction to form a relatively circular antenna assembly with quadrupole symmetry. Thus, the lowest asymmetric moments of antenna assembly 500 may be octapole.

As can be appreciated from the foregoing, antenna assembly 500 may be implemented with a plurality of non-circular coils eccentrically arranged to offset at a predetermined angle in the azimuthal direction, in an embodiment. In an embodiment, each non-circular coil may be implemented with a plurality of segments disposed on a plurality of planes. The segments may be circularly interlaced by employing a plurality of vias at each end of each segment arranged to align and overlap for the coupling a first segment on a first plane with a second segment on a second plane, in an embodiment.

In contrast to prior art, circular antenna assembly 500 with four non-circular coils circularly interlaced may be quadrupole invariant, i.e., the quadrupole moments may be symmetric to a 90 degree rotation in the azimuthal direction with the lowest order of asymmetry of octapole moments. The amplitude of the octapole moments may be about one half (½) to one quarter (¼) of a percent in contrast to the amplitude of the quadrupole moments of about one percent. Thus, the azimuthal plasma density uniformity across the substrate may be significantly improved, translating into improved yield, by employing a quadrupole invariant TCP inductor coil assembly in contrast to the dipole invariant TCP inductor coil assembly of prior art.

As can be appreciated by those skilled in the art, the optimization of the TCP inductor coil assembly employing a plurality of non-circular coils to balance differing design requirements, e.g., azimuthal asymmetry, radial uniformity, capacitive coupling, multiple feed lines asymmetry, and/or manufacturability, may be a non-trivial and non-obvious task.

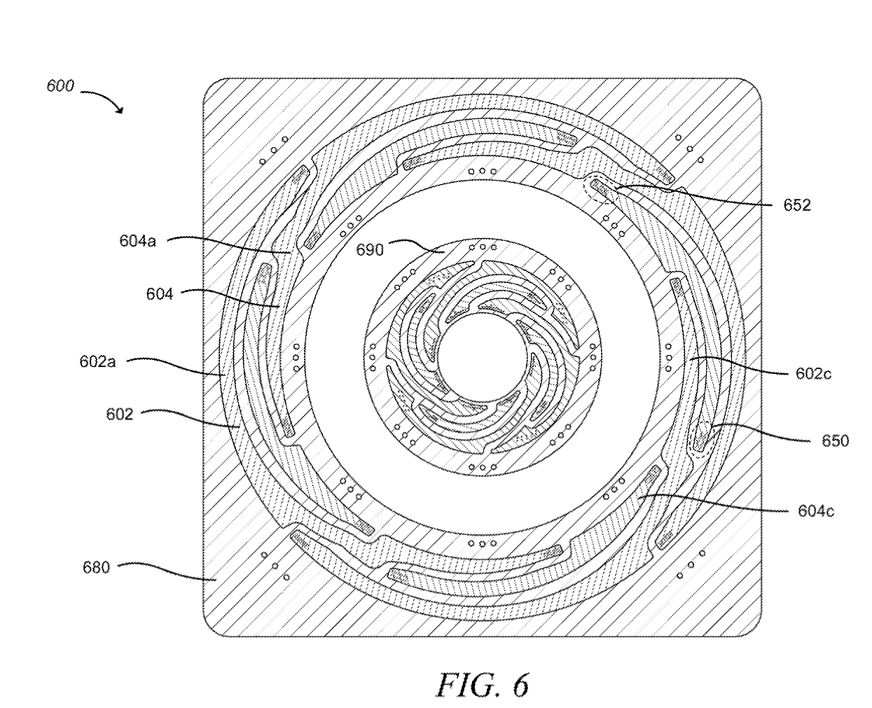

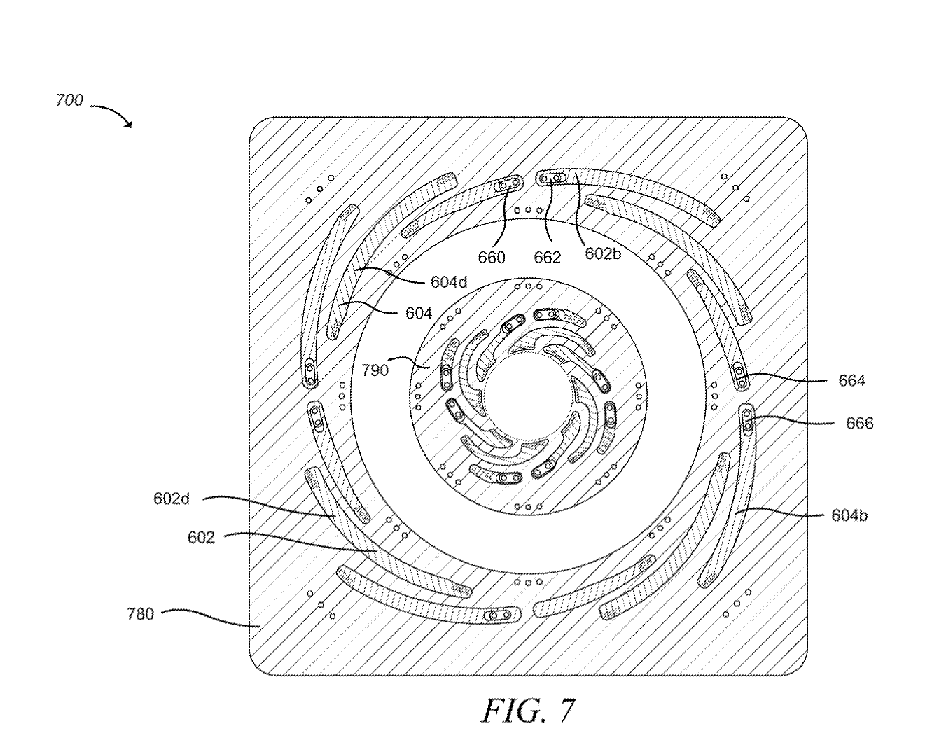

FIG. 6 shows, in accordance with an embodiment of the invention, a simplified schematic of the bottom view of a coil side 600 of an arrangement of antenna assemblies. FIG. 7 shows, in accordance with an embodiment of the invention, a simplified schematic of the top view of a terminal side 700 of an arrangement of antenna assemblies. FIGS. 6 and 7 may be discussed together to facilitate understanding of the antenna assemblies.

Aforementioned, the PCB may comprise of two sides, e.g., coil side 600 of FIG. 6 and terminal side 700 of FIG. 7, in an embodiment. Referring to FIG. 6, the arrangement of antenna assemblies may be configured with at least two set of inductor coils, i.e., an outer set of circular inductor coils/antenna assembly 680 and/or an inner set of circular inductor coils/antenna assembly 690, in an embodiment. Outer set of circular antenna assembly 680 and/or inner set of circular antenna assembly 690 may be independently powered and/or controlled to optimize for radial uniformity of plasma density, in an embodiment.

By employing multilayers PCB and/or inter-layer vias, multiple turn coils, e.g., spiral coil, may be fabricated in a planar format. The basic shape of each coil winding may be a single turn distorted circle, e.g., an ovoid shape that may be implemented employing PCB fabrication technologies. Furthermore, the antenna assembly may be self supporting without the need for an expensive ceramic support structure, in contrast to the spiral coil design of prior art, which may require a lot of assembly. In an embodiment, simple stand offs and/or plastic support may be sufficient for supporting the arrangement of antenna assemblies.

In the implementation of FIGS. 6 and 7, the segments may be fabricated from silver-plated, copper traces with a protective conformable polymer coating on top to increase breakdown voltages, in an embodiment. The traces may be designed to withstand up to about 10 Kilovolt (KV), in an embodiment. For example, the copper sheet for the conductor traces may be sufficiently thicker than about 3 mil. The traces may be manufactured employing conventional PCB fabrication techniques.

The PCB fabrication technologies, e.g., photo lithography/masking, etching/plating, and or computer numerical control machining, may enable multiple layers, interlayer vias, complex shapes in design of segments, and/or multiple arc segments coils to be employed in the design of the antenna assembly. By employing PCB fabrication technologies, the antenna assemblies may be manufactured inexpensively with more consistency and accuracy in mechanical and electrical terms in contrast to the double spiral air core coils of prior art.

As can be appreciated by those skilled in the art, the design of a circular antenna assembly comprising a set of non-circular coils may be problematic. First, the set of non-circular coils may not touch each other because allowing the coils to touch may cause a short. Second, the set of non-circular coils may need to circularly interlace to form a circular TCP inductor coil assembly with minimal azimuthal asymmetry. Third, the set of non-circular coils may be interwoven in the z-direction to minimize non-uniformity from the plasma standpoint.

Aforementioned, each circular inductor coil assembly may be implemented with at least four circularly interlaced non-circular coils offset at a 90 degree angle to reduce azimuthal asymmetry, in an embodiment. In an example, each non-circular coil may be configured with a plurality of segments circularly interlaced between the two planes of the PCB. Each segment may comprise of a plurality of vias at each end of the segment. The segments may be coupled to each other by overlapping and/or aligning the plurality of vias at a first end of a first segment dispose on the first plane of the PCB with the plurality of vias at the second end of a second segment dispose on the second plane of the PCB. The four segments may be consecutively coupled in the z-direction between the two planes of the PCB, i.e., circularly interlaced, to form a non-circular coil.

In the implementation of FIGS. 6 and 7, outer circular antenna assembly 680 may be configured with at least a set of four non-circular coils, in an embodiment. For example, a first non-circular coil 602 may implemented with at least four segments. On the coil side 600 of FIG. 6, outer circular antenna assembly 680 may be configured with at least two segments 602a and 602c of first non-circular coil 602, in an embodiment. On the terminal side 700 of FIG. 7, outer circular antenna assembly 780 may be configured with at least two segments 602b and 602d of first non-circular coil 602, in an embodiment. Thus, the four segments of the non-circular coil may be disposed on two different sides of the PCB, in an embodiment.

As shown in FIGS. 6 and 7, each segment may be configured with at least two ends, in an embodiment. In an example, segment 602c of FIG. 6 may be configured with a first set of vias at the first end 650 and/or a second set of vias at the second end 652. To circularly interlace the consecutive segments between the two sides of the PCB, the set of vias at each ends of adjacent segments on the different sides of the PCB may be overlapped and aligned to allow for coupling of the segment through the aligned set of vias.

For example, non-circular coil 602 may be circularly interlaced by consecutively coupling in the z-direction a first end of segment 602a on coil side 600 (FIG. 6) of the PCB with a second end of segment 602b on coil side 700 (FIG. 7) of the PCB. Next, a first end of segment 602b may be coupled with a second end of segment 602c on coil side 600 (FIG. 6) of the PCB. Then, a first end of segment 602c may be coupled with a second end of segment 602d on terminal side 700 (FIG. 7) of the PCB. Finally, a first end of segment 602d may be coupled with a second end of segment 602a to form a non-circular coil, in an embodiment.

In the implementation of FIGS. 6 and 7, a second non-circular coil 604 may be circularly interlaced in a similar method employing four segments 604a, 604b, 604c, and 604d on the PCB with the two sides. First non-circular coil 602 may be identical to second non-circular coil 604, in an embodiment. Furthermore, non-circular coil 604 may be eccentrically arranged to be offset by 90 degrees in the azimuthal direction from non-circular coil 602, in an embodiment. For example, segment 604a may be arranged eccentrically on the PCB board to be offset by 90 degrees in the azimuthal direction from segment 602a. Likewise, segments 604b, 604c, and 604d may be arranged eccentrically on the PCB board to be offset by 90 degrees in the azimuthal direction from segments 602b, 602c, and 602d, respectively. Thus, circularly interlaced, non-circular coil 604 may be offset by 90 degrees from circularly interlaced, non-circular coil 602.

In an embodiment, the remainder of the non-circular coils may be similarly offset and circularly interlaced to form a circular antenna assembly.

As may be appreciated from the foregoing, the antenna assembly employing a plurality of non-circular coils may be arranged, i.e. offset by a predetermined angle, as to not be in physical contact to prevent shorting the circuit of each coil. The prevention of physical contact between each coil may be accomplished by segmenting each non-circular coils into a plurality of segments. Each segment of the non-circular coil may be disposed on alternative sides of the PCB and coupled in the z-direction by vias. Similarly, the next non-circular coil may be circularly interlaced in a similar method but may be arranged eccentrically to be offset by a predetermined angle in the azimuthal direction from the first non-circular coil, in an embodiment. The process may be repeated for all the coils in the set of non-circular coils to form the circular antenna assembly, in an embodiment. Thus, all the non-circular coils may be circularly interlaced between the two sides of the PCB without any physical contact between each coil to cause a short.

As the term is employed herein, the predetermined offset angle between each coil in the azimuthal direction may be computed by dividing the number of coils in the circular antenna assembly by 360 degrees. As may be appreciated by the foregoing, the shape of the non-circular coils may be optimized to a predetermined shape, e.g., an ovoid shape, to be eccentrically arranged by a predetermined offset angle in the azimuthal direction to form the circular antenna assembly with minimal azimuthal asymmetry. By employing four non-circular coils with a 90 degree offset angle between each coil, for example, the circular antenna assembly as shown in FIGS. 6 and 7 may be quadrupole invariant with the lowest asymmetric moments of octapole. Thus, the azimuthal non-uniformity of the antenna assembly may be minimized.

Furthermore, when multiple coils are significantly overlayed on the same footprint area there may be considerable mutual flux coupling and hence inductance may be maintained. For example, the coils may be driven in parallel from a common supply without the excessive four-fold reduction in load impedance that might be expected. In practice a reactance reduction of less than about 50% may be possible. Thus, the behavior of higher inductance of a multiple-turns coil may be achieved with a plurality of single-turn coils through mutual flux coupling.

An advantage of circularly interlacing a plurality of non-circular coils between the two planes of the PCB may be the averaging effect of interweaving the coils in the z-direction between the two planes of the PCB, in an embodiment. Referring to FIG. 5, the four coils 502, 504, 506 and 508 may be shown to interweave in the z-direction to form a circular antenna assembly wherein the coils may be average from top to bottom for all coils, in an embodiment. Aforementioned, TCP antenna assembly may typically be disposed on top of the plasma processing chamber. From the plasma perspective, plasma in the processing chamber may see an average voltage, i.e., no hot spot or fluctuation in voltage, from the coils of the antenna assembly.

Although TCP antenna assembly may be inductively coupled to plasma through a quartz window, the coupling between the TCP antenna assembly and plasma may not be a pure inductive mode. The coupling between the TCP antenna assembly and plasma may have between about 10 to about 30 percent capacitive coupling. The capacitive coupling between the TCP antenna assembly and plasma in a plasma processing system may be vital in cases such as igniting and/or sustaining plasma.

Consider the situation wherein, for example, electronegative gases such as SF₆ and/or NF₃ may be employed for plasma processing. The voltage from the inductive loop may not provide sufficient energy to interact with the electronegative gas to reliably ignite plasma. Capacitive coupling may be more efficient at plasma ignition under the aforementioned situation.

Consider another situation wherein, for example, electronegative gases such as SF₆ and/or NF₃ may be employed for plasma processing at relatively low power. The transition from a capacitive coupling to an inductive coupling may induce instability due to high amount of low energy electrons being drawn from plasma. Controlled capacitive coupling to plasma may be desired to maintain stable operation.

In general capacitive coupling may be accentuated by increasing the surface area. As shown in FIG. 6, coil side 600 of the PCB is the plasma facing side. In an embodiment, the segments of the coils facing plasma on the antenna assembly may be designed with notches, extensions, and/or curves to maximize surface area to capacitively couple to plasma. Furthermore, the current flow on the coil side 600 of the PCB may be non-existent. Thus, the effect of maximizing surface area of the segments of the coils facing plasma may have minimal effect on inductive coupling while maximizing capacitive coupling to plasma.

In contrast to the coil side 600 of the PCB of FIG. 6, the surface area of the segments of the coils on terminal side 700 of the PCB of FIG. 7 may be minimized to decrease capacitive coupling to reduce stray capacitance.

Alternatively, a third PCB layer may be employed to implement an electrostatic shield at the bottom of the PCB to deal with capacitive coupling, in an embodiment. For example, the shield layer may be slotted to prevent excessive eddy currents and/or either grounded or connected to its own RF power source at a predetermined frequency. The predetermined frequency may be either the same as and/or different from the frequency of operation. Thus, capacitive coupling problem may be minimized by employing a third PCB layer as electrostatic shield.

Aforementioned, the basic shape of each coil winding may be a single turn distorted circle. An advantage of the coil winding being a single turn may be in the implementation of termination points for RF feed to the coils. As shown in FIG. 6 and FIG. 7, outer antenna assembly may be configured with four individual non-circular coils. Each non-circular coil in the set of four coils may be supplied with terminal points anywhere along the single turn of each distorted circle, in an embodiment.

In an example, RF feed to non-circular coil may be implemented as shown in FIG. 7. Segment 602b of first coil 602 may be configured with a first terminal 660 and a second terminal 662, in an embodiment. Similarly, segment 604b of second coil 604 may be configured with a third terminal 664 and a fourth terminal 666, in an embodiment. Furthermore, the remainder coils may similarly be implemented with terminal points for RF feed. In an embodiment, each set of terminals on each single turn coil may be offset by a predetermined angle, e.g., 90 degree angle, to minimize azimuthal asymmetry. Thus, the predetermined angular offset of each non-circular coil provide placement of terminal points on each coil to further improve azimuthal uniformity for the antenna assembly.

The RF feed to the coils may be separated and externally synchronized, in an embodiment. Alternatively, in another embodiment, the RF feed may be from a common RF point via equal length lines of equal impedance. In an example, a single and/or multiple parallel feeds such as 50 Ohm transmission lines may be employed, e.g., two feeds in parallel may give a 25 Ohm line. However, if the feeds are kept really short, the characteristic impedance may be unimportant.

Alternatively, strip line type transmission lines may be employed, in an embodiment. In an example, the transmission line may be implemented by sandwiching an RF hot copper strap between two wider ground straps with dielectric separators such as a Teflon tape or foamed Teflon as the insulator. Thus, the transmission line may be able to stand off the high voltage, carry high current and/or result in a very low impedance flexible feed line at low cost.

In an embodiment, the capacitive coupling may advantageously lower costs by simplifying termination arrangements, e.g., an unbalanced operation where one end of each coil winding may be grounded directly and/or by a fixed terminating reactance, typically a capacitor. Conversely, in an embodiment, a balanced operation may be employed to minimize capacitive coupling and ensure no net current flow to the plasma.

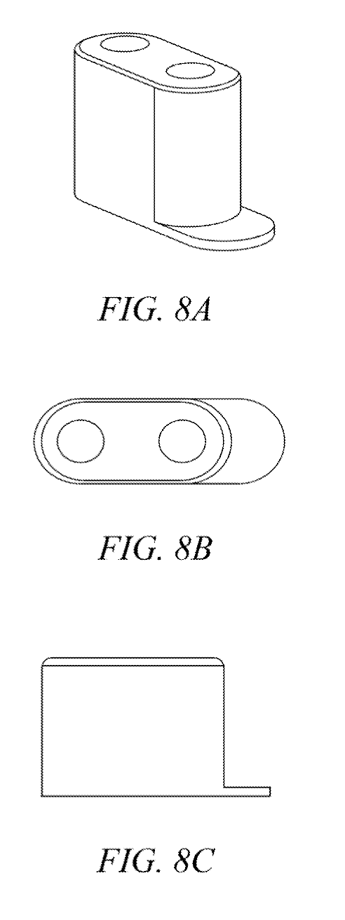

FIG. 8 shows, in accordance with an embodiment of the invention, three different views of a terminal block. FIG. 8A shows an isometric view of the terminal block. FIG. 8B shows a top view of the terminal block. FIG. 8C shows a side view of the terminal block. The terminal block may be implemented by screwing onto the PCB at a predetermined position along the coil.

In contrast to prior art, the terminal points on each coil may be configured relatively close to each other resulting lower looping magnetic field. Whereas, the prior art spiral coil may required RE feed to be supplied to a terminal point inside of the spiral coil and to a terminal point outside of the spiral coil. To make the electrical connection, a bridge in the radial direction may be required. Since the terminals points of the prior art may not be close together, a relatively larger looping magnetic field may induce non-uniformity in plasma.

As can be appreciated from the foregoing, one or more embodiments of the invention provide for an antenna assembly employing PCB fabrication technologies for lower cost and higher manufacturability. By employing multiple PCB layers, inter-layers vias, non-circular coils, and circularly interlacing, a circular antenna assembly may be implemented that may be quadrupole invariant with negligible octapole moments asymmetry in the azimuthal direction. Advantageously, arrangement of antenna assemblies being configured with a plurality of separate antenna assemblies may improve plasma uniformity in the radial direction across the substrate. By maximizing the surface area of the segments on the coil side of the PCB, capacitive coupling with plasma may be increase to improve the reliability of igniting and/or sustaining plasma. Thus, the plurality of benefits from the circular antenna assembly may allow higher yield of electronic devices at lower operating cost.

While this invention has been described in terms of several embodiments, there are alterations, permutations, and equivalents, which fall within the scope of this invention. Although various examples are provided herein, it is intended that these examples be illustrative and not limiting with respect to the invention. It should also be noted that there are many alternative ways of implementing the methods and apparatuses of the present invention. Furthermore, embodiments of the present invention may find utility in other applications.

Also, the title is provided herein for convenience and should not be used to construe the scope of the claims herein. If the term “set” is employed herein, such term is intended to have its commonly understood mathematical meaning to cover zero, one, or more than one member. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents as fall within the true spirit and scope of the present invention.

What is claimed is:

1. An antenna arrangement in a plasma processing system for providing plasma uniformity across a substrate during substrate processing, comprising:
a plurality of circular antenna assemblies, wherein each circular antenna assembly of said plurality of circular antenna assemblies includes a set of non-circular coils, wherein each non-circular coil of said set of non-circular coils is offset at a predetermined angle in an azimuthal direction; and
a set of power generators for powering said plurality of circular antenna assemblies.

2. The arrangement of claim 1 wherein said each circular antenna assembly is fabricated utilizing a printed circuit board (PCB)

3. The arrangement of claim 2 wherein said PCB is configured with at least two sides, wherein said at least two sides include
a coil side, and
a terminal side.

4. The arrangement of claim 3 wherein said plurality of circular antenna assemblies includes at least a first circular antenna assembly and a second circular antenna assembly, wherein said second circular antenna assembly surrounds said first circular antenna assembly.

5. The arrangement of claim 4 wherein an inner radius of said first circular antenna assembly is different from an inner radius of said second circular antenna.

6. The arrangement of claim 4 wherein an outer radius of said first circular antenna assembly is different from an outer radius of said second circular antenna.

7. The arrangement of claim 3 wherein said set of non-circular coils for said each circular antenna assembly includes at least four non-circular coils circularly interlaced.

8. The arrangement of claim 7 wherein said offset between said each non-circular coil of said set of non-circular coils is calculated by dividing the number of coils in said each circular antenna assembly by 360 degrees.

9. The arrangement of claim 8 wherein said offset between said each non-circular coil of said set of non-circular coils is at a 90 degree angle in said azimuthal direction.

10. The arrangement of claim 8 wherein said each non-circular coil of said set of non-circular coils includes a plurality of segments.

11. The arrangement of claim 10 wherein said plurality of segments is a plurality of conductive traces.

12. The arrangement of claim 11 wherein said plurality of conductive traces includes a plurality of silver-plated, copper traces.

13. The arrangement of claim 10 wherein said plurality of segments includes at least four segments comprising
a first segment disposed on said coil side of said PCB,
a second segment disposed on said terminal side of said PCB,
a third segment disposed on said coil side of said PCB, and
a fourth segment disposed on said terminal side of said PCB.

14. The arrangement of claim 13 wherein each segment of said at least four segments includes two ends, wherein each end of said two ends includes plurality of vias and wherein said each segment is circularly interlaced with one another by coupling said plurality of vias on adjacent segments, wherein said adjacent segments are positioned on different side of said PCB.

15. The arrangement of claim 13 wherein said each non-circular coil is circularly interlaced in a z-direction wherein
a second end of said first segment is coupled with a first end of said second segment,
a second end of said second segment is coupled with a first end of said third segment,
a second end of said third segment is coupled with a first end of said fourth segment, and
a second end of said fourth segment is coupled with a first end of said first segment.

16. The arrangement of claim 3 wherein said coil side of said PCB is a plasma facing side.

17. The arrangement of claim 16 wherein each segment of said each non-circular coil that is disposed on said coil side has a surface area greater than each segment of said each non-circular coil that is disposed on said terminal side.

18. The arrangement of claim 3 wherein a third PCB layer is employed to implement an electrostatic shield at the bottom of said PCB to handle capacitive coupling.

19. The arrangement of claim 1 wherein said each non-circular coil of said set of non-circular coils is powered by a separate power generator of said set of generator.

20. The arrangement of claim 1 wherein said set of non-circular coils is powered by a single power generator of said set of generators.
